(19) United States
(12) Patent Application Publication
(10) Pub. No.: US 2008/0029386 A1
(43) Pub. Date: Feb. 7, 2008

(54) Method and apparatus for trans-zone sputtering

(76) Inventor: Benjamin F. Dorfman, San Francisco, CA (US)

Correspondence Address: HODGSON RUSS LLP;THE GUARANTY BUILDING, 140 PEARL STREET, SUITE 100, BUFFALO, NY, 14202-4040, US

(21) Appl. No.: 11/497,088

(22) Filed: Aug. 1, 2006

(51) Int. Cl. C23C 14/00

(52) U.S. Cl. 204/192.12

(57) ABSTRACT

A new method of surface engineering of materials employs ion sputtering from a limited area, or sputter zone, of the surface of said materials, and the deposition of the sputtered matter upon a separate or other limited area, or deposition zone, of the surface of the same or simultaneously surface engineered second material, while the sputter and deposition zones are moving synchronously and simultaneously relative to the surface subjected to surface engineering. When the surfaces of two materials are simultaneously engineered, the flux of particles ejected from the sputter zone of the first material are directed to and deposited upon the surface of the deposition zone of the second material, and vice versa; hence, two different materials each possessing both sputter and deposition zones are subjected to surface engineering at the same time resulting in an exchange of surface layers.
The new method is named Trans-Zone Sputtering.

Where it is applicable, especially in precise surface engineering and ultra-thin film deposition technologies, Trans-Zone Sputtering is characterized by exceptionally high productivity; it does not require expensive consumable targets, and in some instances it avoids the necessity of water cooling, thus simplifying the process and reducing the weight, while simultaneously allowing a thinner magnetron and increasing the effectiveness of the magnetron cathode assembly; it also simplifies the maintenance of the equipment, reduces labor requirements and virtually avoids harmful emissions often occuring with this technology during the equipment maintenance.

### BACKGROUND OF THE INVENTION

1. Field of the Invention

The present invention relates to surface nano-engineering using ion sputtering, in particular planar magnetron sputtering, and vacuum deposition of ultra-thin films, typically with thicknesses not exceeding a few hundred angstroms. It especially concerns highly productive surface treatment of materials that may be formed and commercially used as flexible sheets and tapes, including plastics, metals, or composite materials.

2. Description of the Related Art

Over the past few decades, the ion sputtering, especially magnetron sputtering, and in particular, planar magnetron sputtering, revolutionized many industries including microelectronics, data storage, displays, optics, fiber optics, physical instrumentation, telescopes, glass and glazing industry, aerospace and defense applications, automotive industry, decorative coatings, energy technology, lighting, medical applications, and protective coatings.

Magnetron sputtering is a powerful alternative to less effective vacuum evaporation and extremely emissive and harmful electrochemical deposition. Because sputtering may be realized from the surface of virtually any solid material feasible for vacuum technology, and in principle it does not directly depend on the melting point or vapor pressure of the sputtered material, sputtering represents a nearly universal approach for thin film deposition.

Specifically, the term sputtering defines a vacuum process of induced ejection of neutral or charged, mono-atomic, or multi-atomic particles, or molecular radicals from the solid surface exposed to bombardment with energetic particles, most often with field accelerated atomic ions, usually argon ions. More generally, the term sputtering is commonly applied to a two-step technological process comprising ion-induced ejection of sputtered particles (in the above given definition), and condensation, or deposition, of the sputtered matter upon another solid surface. The consumable solid ejecting flux of sputtered particles under bombardment is called a “target”. The solid upon which surface the sputtered particles condense is designated as the substrate. Only a portion of matter sputtered from the surface of the target reaches the surface of the substrate, depending on the useful deposition area, e.g. relative size of the substrate, and the distance between target and substrate. The remaining portion of the flux is lost due to deposition upon the internal surface of the vacuum chamber walls, substrate holder and other internal parts and surfaces. This results in losses of valuable materials and produces undesirable side effects requiring time and labor expenditures and emission control measures. To increase the yield of sputtered matter into the useful product, e.g. the film deposited upon the substrate, the distance between target and substrate should be as low as is physically “allowed” (typically ≧˜2″) and practically feasible.

On the other hand, the effectiveness of target use is not high as well. This is due to the uneven profile of the sputtering rate along of the surface of the target, and because the target cannot be consumed beyond a certain percentage of its initial thickness, typically not exceeding about 50% of initial target thickness in the area of its maximum sputtering rate, because of mechanical requirements. Thus, the use of the targets rarely exceeds 40%. Furthermore, an uneven profile of the partially consumed target results with an uneven profile for the deposited layer as well, especially in the chamber geometry with a short distance between target and substrate; because of uneven profiles, the targets are often changed when only as little as 25% has been consumed.

It should be pointed that in the case of many metals, especially metal possessing high affinity to oxygen, the thickness of a naturally oxidized surface layer may be comparable with the sputtered/deposited thickness. Obviously, [some oxygen will be redeposited from the original surface and may be additionally occluded from the vacuum chamber. However, this effect is usually desirable, especially because such and oxidized layer deposited from relatively high energetic flux upon a fast moving surface would be characterized with exceptionally high density and uniformity.

Typically in the prior art, the uniformity of the film thickness, as well as the uniformity of its composition, structure and physical properties, strongly depends on the uniformity of target erosion during the previous history of its sputtering. To overcome these problems, there have been various proposals of special magnetron geometry designs providing a more uniform plasma, as well as drive mechanisms for magnetron assembly.

The other innate problem of magnetron technique is the extremely high power density upon the surface of consumable target. To provide maximum performance, the magnetron assembly must be designed for maximum power density that can be dissipated while avoiding the melting of the cathode assembly or overheating of other in-chamber parts. The most productive magnetrons in the industry, such as the circular and rectangular magnetrons of Angstrom Sciences, Inc. are designed for power density up to −40 W/cm (sup2), or 250 W/in(sup2). The target is water-cooled during the sputtering with relatively high water consumption, and the magnetron sputtering device is usually mounted over a sputtering opening in the external wall of the vacuum chamber. More specifically, the direct water cooling of the target is necessary to provide maximum performance; hence, in such an assembly the target installation must provide a high vacuum seal of the water cavity or channels and must be sufficiently thick to sustain the atmospheric pressure. In addition, the entire target assembly comprising of internal water cooling channels experiences the full atmospheric pressure and must be designed with considerable thickness to overcome the resultant bending forces. As a result, magnetron assemblies are heavy devices. For instance, a medium size magnetron, such as circular planar ONYX-16 DIRECT magnetron produced by Angstrom Sciences, Inc. with RF maximum sputtering power 16 Kilowatts requires a water flow rate of 13 GPM and weighs 220 Pounds. Not only does it increase the cost of production, installation and maintenance of the equipment, but it limits the possibility in optimizing the magnetron design, because the maximum sputter-deposition rate requires the target assembly having as thin a cross-section as possible. And, as demand for processing larger substrates continues, the size of the cathode assembly is scaled accordingly, while the weight increases progressively.

Sputtering is also commonly applied as an independent process for surface cleaning prior to various technological processes, including a variety of deposition processes, not necessarily from sputtering flux. In such a case, the substrate material subjected to cleaning serves as consumable target, while the sputtered matter deposited upon the inside walls of vacuum chamber is virtually lost.

The present invention solves all these problems in the field of the surface nano-engineering and ultra-thin film deposition technologies.

### SUMMARY OF THE INVENTION

A new method of surface engineering is based on vacuum deposition from the flux of atomic, multi-atomic, and/or molecular particles, neutral and/or charged, generated by ion sputtering, especially planar magnetron sputtering; it is distinguished from the prior art in that that the flux of said particles is generated by ion sputtering from the surface of the same material. More specifically, the flux is generated by magnetron sputtering from a limited zone of said material surface, and the deposition is realized on another zone of the same treated material. It is also possible that two different materials are used for each of the sputtering and deposition zones.

The new method is named Trans-Zone Sputtering.

There are two major embodiments of the new method:

1. Trans-zone sputtering wherein the particles ejected from a sputter zone of anytreated material, condense backwards onto the deposition zone upon the surface of the same material from which these particles were ejected via sputtering. The useful effect is attained due to certain special properties of the deposited layer, especially in the case of polymer materials where the layer deposited from relatively high-energetic carbon-containing particles is enriched by sp(sup3), or covalent bonded carbon, also known as diamond-like carbon. Also the deposited layer is virtually free of nano-pores, and improves smoothness and tribological properties of the engineered surface.

In the case of surface engineering of metallic materials, the useful effects are attained due to uniformity and fine structure of the deposited layer; additional useful effects, such as high hardness, amorphous atomic arrangement, anti-corrosion protection, as well as modified magnetic properties may be achieved as well, especially by introducing doping elements into the sputtered flux.

2. Trans-zone sputtering with surface layers exchanges between two different simultaneously treated materials each possessing sputter and deposition zones subjected to surface engineering. In this embodiment all the above listed useful effects may be produced, as well as simultaneous deposition of an electrically conductive metallic layer upon plastic, and an insulating and/or anti-corrosion polymer layer upon metal. If desired, decorative effects may also be produced.

In both major embodiments indicated above, the sputter zone or zones, and the deposition zone or zones are moving synchronously relative to the material subjected to surface engineering. This still may imply two additional embodiments of the invention: in one embodiment[the main above refers to synchronously moving materials] the treated material is moving relative to the chamber, while the positions of sputter and deposition zones are fixed relative to the chamber; in a generally less preferable embodiment, the position of the treated material is fixed relative to the chamber, while the sputter and deposition zones are moving relative to the chamber.

Most preferably, the treated material is relatively flexible and possesses a tape-like shape, and the tape is continuously moving through the sputtering/deposition chamber. One or two sides of the tape may be treated simultaneously in the continuous process.

The new method, in particular is based on RF magnetron sputtering, and is especially feasible for dielectric materials, such as various polymers. But it may also be Trans-Zone Sputtering implies a deposition upon a fast moving substrate, and it is characterized with an especially high space uniformity of both, sputtering and deposition.

Where it is applicable, especially in the precise surface engineering and super-thin film deposition technologies, Trans-Zone Sputtering is characterized with exceptionally high productivity; it does not require expensive consumable targets; it simplifies the maintenance of equipment, reduces labor requirements and virtually avoids emissions: after many processes, cleaning of the chamber will be required, but this is after kilometers of tape has been produced virtually without emissions. Because of the reduced frequency of chamber cleaning, the dust generated from cleaning is reduced.

Further, Trans-Zone Sputtering represents true surface engineering because said engineering takes place on the first few atomic layers only, and because the time gap between surface cleaning and deposition is greatly reduced. Indeed, this time gap is 2 or 3 orders of magnitude shorter than in other deposition techniques known from the prior art. Correspondingly, Trans-Zone Sputtering allows a decreased adsorption of uncontrolled impurities on pre-cleaned surfaces by about 100 to 1000 fold. It is important to note that the surface cleaned by sputtering is extremely active. Often, a very expensive ultra-high vacuum technique is used to minimize undesired absorption. Trans-Zone Sputtering allows one to simplify these vacuum requirement proportionally.

On the other hand, during the Trans-Zone Sputtering, the sputtering process carries simultaneously both functions—cleaning of the surface prior to deposition and generating the source flux for said deposition, because material ejected from the surface in the Sputter zone is instantly applied for surface engineering in the deposition zone. employed for metals being insulated from the magnetron cathode with a thin dielectric or a narrow vacuum gap.

The new method does not require special consumable targets, and the yield of sputtered matter into useful coatings can exceed 90%. In addition, the distribution of the deposition rate along the surface is extremely uniform because the consuming surface (surface in sputter zone) always preserves its initial smoothness, and because both the target consuming surface(surface in the sputter zone) and the growing substrate surface (surface in deposition zone) are continuously moving with high speed relative to the sputter zone and deposition zone, respectively.

There is no need in water cooling of the magnetron assembly. As a result, the entire magnetron assembly may be located inside the chamber, and it does not experience the force of atmospheric pressure. Thus, the cathode assembly becomes thinner, the magnetic design is optimized, and the effectiveness of sputtering, the sputtering/power density ratio and energy use all improve. It also reduces the magnetron weight, thus simplifying its installation into the chamber and allowing for a movable design.

An additional advantage is an exceptional uniformity (less than 1% variation) of both sputtering and deposition processes and smoothness of the resulting surfaces due to high speed movement of the consuming and “growing”/deposition surfaces relative to the cathode assembly.

As it is understood from a general consideration of the vacuum deposition technology, as well as from the prior art practices, deposition upon a moving substrate equalizes nonuniformity of flux and, hence, produces films which are more uniform by chemical composition, surface morphology, and physical or chemical properties.

Hence, in Trans-Zone Sputtering, the material removed during cleaning becomes the material deposited during coating on the same or another previously cleaned surface; the resulting surface is now uniform, high energy, clean and with doping if desired.

Furthermore, the sputtering process automatically, by design, realizes the necessary surface preparation in situ in the sputter zone, prior to deposition in the deposition zone. As the result, the productivity of sputtering-deposition process is essentially higher than in prior art, the labor expenses are lower, and emission during the equipment cleaning dramatically decreases. Although the scope of applications of Trans-Zone Sputtering is confined to ultra-thin surface layers, it provides a powerful technological tool for many industries, and it makes the ion sputtering technique economically sound even in such application fields where it was not feasible based on prior art, such as the field of surface engineering in mass production for the plastic industry.

### BRIEF DESCRIPTION OF THE DRAWINGS

FIG. 1 is a simplified schematic diagram of trans-zone sputtering system for one-side surface engineering of one tape-shaped material with a parallel “counter flow” orientation of sputter and deposition zones.

FIG. 2 is a simplified schematic diagram of trans-zone sputtering system for two-side surface engineering of one tape.

FIG. 3 is a simplified schematic diagram of trans-zone sputtering system for one-side surface engineering of one tape-shaped material with additional doping from plasmatron source.

FIG. 4 is a simplified schematic diagram of trans-zone sputtering system for surface engineering of two materials synchronously.

FIG. 5 is a simplified schematic diagram of trans-zone sputtering system for surface engineering with a movable magnetron.

### DETAILED DESCRIPTION OF THE PREFERRED EMBODIMENT(S)

### Definitions

1. Sputter Zone—area or “zone” of the material (typically thin film or tape) where its surface becomes the Target surface or Sputtered surface as its existing surface provides material to be sputtered into the deposition zone. In any given moment of the Trans-Zone Sputtering process, the Sputter Zone is located in vicinity of the negative bias electrode of the magnetron assembly, although the relative position of the Sputter Zone is continuously moving with regard to said material.

2. Deposition Zone—area or “zone” of the material (typically thin film or tape) where its surface becomes the Deposition surface as its existing surface provides the area to receive the previously sputtered material. In any given moment of the Trans-Zone Sputtering process, the Deposition Zone is directed to the flux of the sputtered matter ejected from the Sputter Zone, although the relative position of the Deposition Zone is continuously moving with regard to said material.

3. SputtersputterSurface Engineering—as is generally understood in the industry, without limitation; in general, and for clarification only, it refers to a surface of any material that is undergoing any form of restructuring or modification.

4. Target/Sputtered Surface—The surface of any material that in the area of the Sputter Zone where a portion of that material's surface provides material for the flux to be subsequently sputtered onto a Deposition Surface in the Deposition Zone.

5. Deposited Surface—The surface of any material in the area of the Deposition Zone where the material will receive material from the flux generated by previously sputtered material.

6. Simultaneously Engineered—referring to two materials where each is providing material for a flux in the Sputter Zone and at the same time, the flux is deposited on the other respective material in the Deposition Zone.

### DESCRIPTION OF THE INVENTION

In the below description and throughout this application, the use of the word “tape” to describe the material that is engineered is not limiting. “Tape” is a general term and also implies any type of thin films or other “tape-like” or “film-like” material which may or may not be processed or delivered in a roll.

In accordance with the present invention, deposition of the sputtered matter, such as metallic, polymeric, or ceramic materials, on the surface of identical material significantly improves various surface properties, including tribological properties, surface hardness, and in some cases fracture toughness. Except for fracture toughness, these surface property enhancements are known in prior art; however, for fracture toughness, if a strong surface layer with strong adhesion is present, there is an increase in the resistance to crack propagation (reference Si reinforcement and glass patent applications here).

In the case of polymers, such as Teflon, such a deposition also decreases or completely closes superficial micro- and nano-pores. Such useful and important improvements are especially effective if a negative bias voltage is applied to the substrate holder with an appropriate design of the magnetron-substrate assembling geometry.

In addition, the doping elements may be introduced together with flux of the sputtered matter to enhance said surface engineering. Doping elements may be introduced as atomic, or molecular, or multi-atomic cluster particles with a complimentary flux from an individual source, such as a complimentary sputtering source, thermal evaporator or external gas supply line. The doping element or combination of different doping elements may be selected from the group of non-metallic elements, such as carbon, silicon, boron, oxygen, and/or the group of metals. More specifically, silicon and oxygen are particularly effective doping elements for improving properties of plastics, while carbon or combination of carbon, silicon and oxygen are particularly effective doping elements for improving properties of metals. According to the present invention, many plastic materials, especially silicones or other silicon-organic polymers may be applied as solid precursors, in particular as the target in RF planar magnetrons in the processes of the surface engineering of metals. On the other hand, metals may be used as doping elements to improve surface thermal resistance, or provide surface electrical conductivity, as well as decorative effects for plastics.

According to the present invention, the surface of the same intact material is subjected to the sputtering and deposition of the flux of sputtered particles in the same process.

Also in accordance with present invention, in every specific moment of the process said sputtering is realized in a limited area, or zone, of the surface of material thereby having undergone surface engineering, while deposition is realized in this specific moment of the process upon the other zone of the surface of material thereby having undergone surface engineering. The sputtered matter is ejected from the material in the sputter zone and deposited upon the surface of the material in the deposition zone. The invented method is named trans-zone sputtering.

The surface engineering by trans-zone sputtering is preferably realized with a DC or an RF planar magnetron.

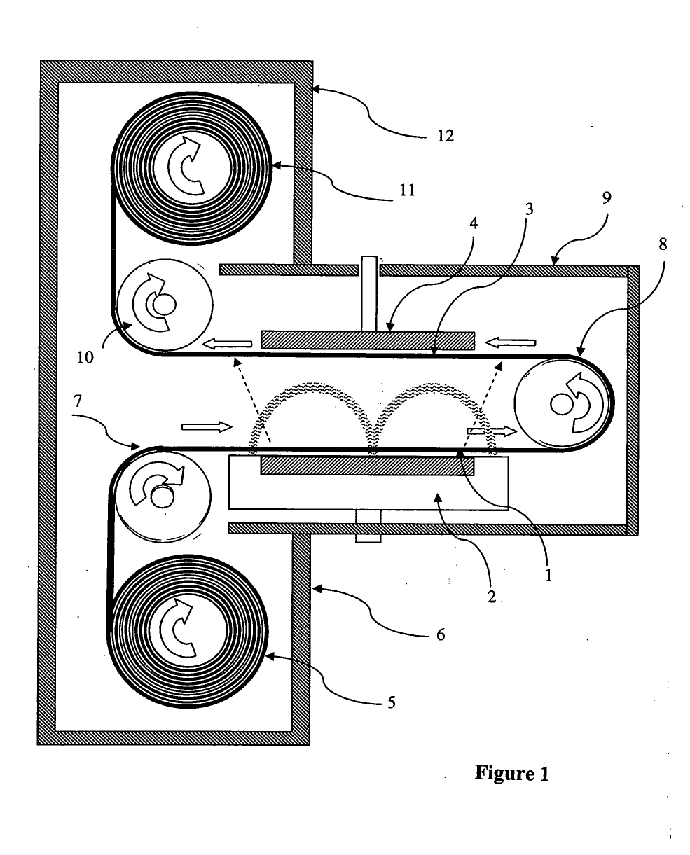

In the main embodiment of the present invention, the sputter zone and the deposition zone are located on the surface of the same intact material. The sputtered matter is ejected from said sputter zone, and the resulting flux of mono-atomic and/or multi-atomic particles are deposited upon the surface of the material in the deposition zone, while both zones are moving synchronously relatively to the surface of said intact material. This is shown in detail in FIGS. 1, 3, and 4. In particular, FIG. 1 shows the trans-zone sputtering system for one-side surface engineering of one tape-shaped material with a parallel “counter flow” orientation of sputter and deposition zones including the following components:

1—sputter zone of the tape of the material undergoing to surface engineering.

2—planar magnetron

3—deposition zone of the tape of the material undergoing to surface engineering.

4—substrate holder-electrode.

5—the feed roll of the tape or film of the material undergoing surface engineering.

6—feed section of the surface engineering system.

7,8,10—drive/guide rolls.

9—deposition section of the surface engineering system.

11—take-up roll of the tape of the material having undergone surface engineering.

12—take-up section of the surface engineering system.

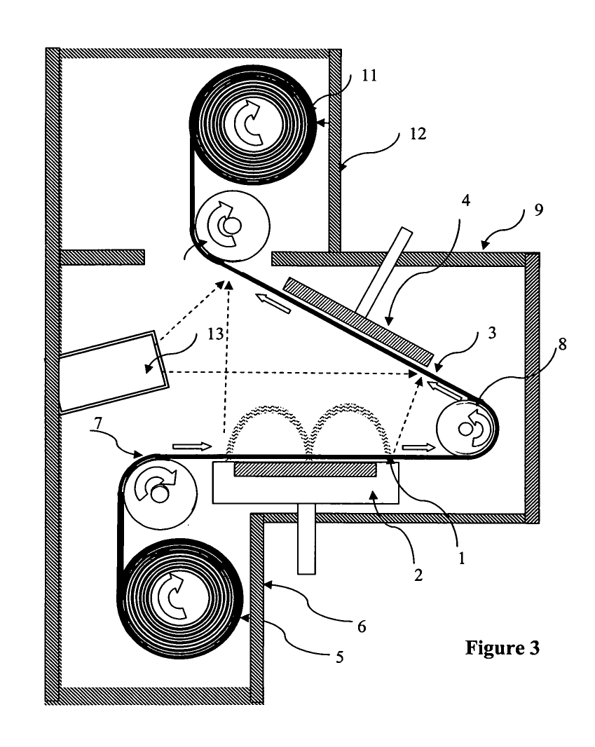

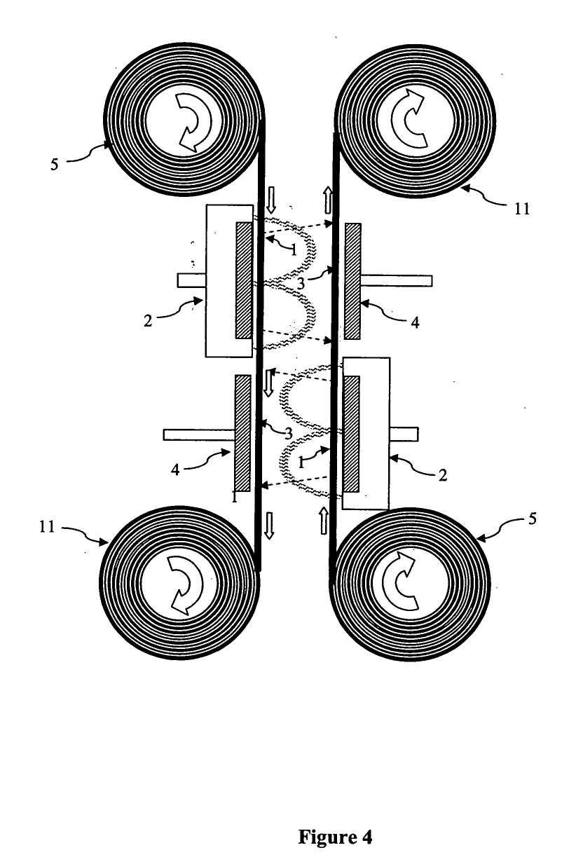

FIG. 3 shows the trans-zone sputtering system for one-side surface engineering of one tape-shaped material with additional doping from plasmatron source including components 1-12 as in FIG. 1 and plasmatron 13. FIG. 4 shows the trans-zone sputtering system for surface engineering of two materials synchronously including components 1-12 as in FIG. 1.

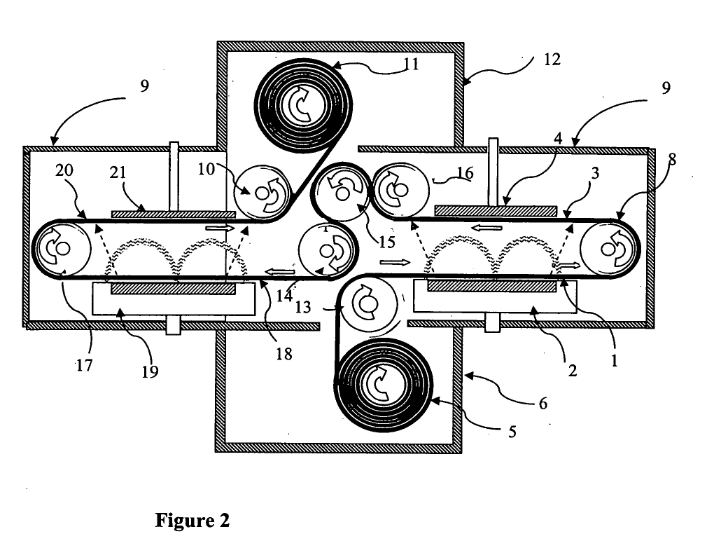

In an alternative embodiment of the present invention, both sputtering and deposition processes are realized upon the surfaces of two separate materials simultaneously, each of said separate materials possess said sputter zone and said deposition zone. The sputtered matter ejected from the sputter zone of the first of two said materials is deposited upon the surface of the deposition zone of the second of two said materials; the sputtered matter ejected from said sputter zone of the second of two said materials is deposited upon the surface of deposition zone of the first of two said materials, both the sputter zone and the deposition zone where each of said materials passes through are fixed relative to the chamber, and the two said materials are moving in parallel but in opposite directions, i.e. counter flow. This is shown in detail in FIG. 2. In particular, FIG. 2 shows the trans-zone sputtering system for two-side surface engineering of one tape including the following components:

1—first sputter zone of the first side of the tape undergoing to surface engineering.

2—first planar magnetron

3—first deposition zone of the tape/film undergoing surface engineering.

4—first substrate holder-electrode.

5—the feed roll of the tape of the material undergoing surface engineering.

6—feed section of the surface engineering system.

7,8,10,13-17—drive rolls.

11—take-up roll of the tape/film of the material having undergone surface engineering.

12—take-up section of the surface engineering system.

18—second sputter zone of the second side of the tape undergoing to surface engineering.

19—second planar magnetron.

20—second deposition zone of the tape undergoing surface engineering.

21—second substrate holder-electrode.

More specifically, the area of material located at any given moment of the process in the proximity of the negative bias electrode, i.e. in the sputter section of the chamber, becomes a Sputter Zone, and in both embodiments of the invention the location of said Sputter Zone moves relatively to the engineered surface covering, consequently, the entire engineered material. Similar consideration is implied to the Deposition Zone. Any given area of the surface of the surface-engineered material becomes a Sputter Zone first and shortly after a period of time it becomes a Deposition Zone.

According to the main embodiment of the present invention, the positions of said sputter zone and said deposition zone are fixed relative to the chamber, said intact material comprising said sputter zone and said deposition zone is moving relative to the chamber, said moving intact material is preferably but not limited to the shape of a tape.

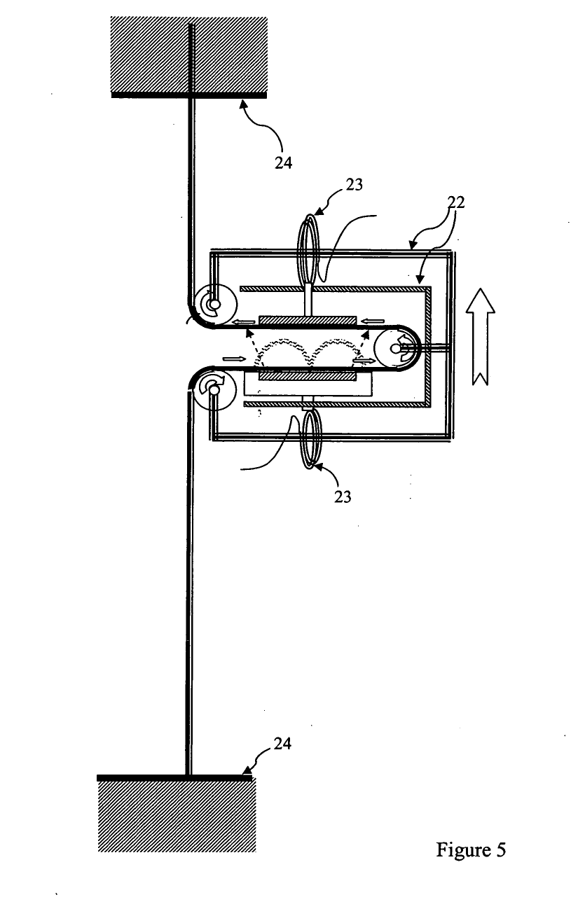

It is also possible according to the present invention, that an intact material comprising said sputter zone and said deposition zone are fixed relative to the chamber, while said sputter zone and said deposition zone are continuously moving relative to the chamber. FIG. 5 shows a very simplified example of such systems. FIG. 5 shows the trans-zone sputtering system for surface engineering with a movable magnetron and including the following components:

22—the movable semi-closed mini-chamber with magnetron and bias electrode (all designations of internal parts as on FIG. 1).

23—flexible contacts.

24—clamps.

A main vacuum chamber encompassing all these parts is not shown in FIG. 5. It is also possible, according to the present invention, to conduct trans-zone sputtering with a magnetron-external bias electrode (or electrodes) assembly allowing surface engineering of unbent and/or inflexible flat materials or structures.

A disclosed method for surface engineering by trans-zone sputtering according to the present invention, especially with regard to the surface engineering of dielectric materials, in particular surface engineering of polymer materials, may be used in combination with a negative potential applied to the special bias electrode (FIG. 1-5) continuously or by a pre-defined timing regime during the entire deposition process. The pre-defined pulse regime is applied during the entire deposition process, while the pulse period time does not exceed the mean deposition time of five mono-layers.

Also in accordance with the most preferable embodiment of the present invention, the intact material comprising said sputter zone and said deposition zone has the tape/film moving relative to the chamber. The length of the tape/film is at least ten times greater than the combined length of the said sputter zone length and said deposition zone length. The tape is moving through said sputter zone being in mechanical contact with the magnetron cathode or at a distance from the cathode not exceeding 5 mm, and the tape is moving through said deposition zone being in mechanical contact with the bias electrode or at a distance from said electrode not exceeding 5 mm.

Typically, according to the present invention, said continuously moving tape/film is guided by a driving mechanism of 180 degrees between said sputter section and deposition section, said sputter section is moving in the opposite parallel direction to said deposition section (FIG. 1). In this embodiment, the surface engineering proceeds upon one side of said material.

In another embodiment of the present invention, said surface engineering is conducted from both sides of said material in one continuous process (FIG. 2). The continuously moving tape/film passes consecutively the first pair of sputter section and deposition section as disclosed in claim 12 wherein the first surface of said moving tape/film is engineered, and the second pair of sputter section and deposition section as disclosed in claim 12 wherein the second surface of said moving tape/film is engineered, the orientation of said tape in inversed on 180 degree with driving mechanism between said first pair of sputter section and deposition section and the second pair of the sputter section.

Still in another embodiment of the present invention, said continuously moving tape/film is guided between said source section and said substrate section by a driving mechanism on the angle at least 90 degrees but no greater than 160 degrees, and an additional flux of ions, atoms and/or low-molecular radicals is directed to said substrate section of said moving tape from an additional source, such as second magnetron, or plasmatron, or evaporating source, or ion gun (FIG. 3).

Also according with the present invention, the surface engineering by trans-zone sputtering is realized upon the surfaces of two different materials simultaneously and in synch, each of two said materials possess said sputter zone and said deposition zone, the sputtered matter ejected from said sputter zone of the first of two said materials is deposited upon the surface of deposition zone of the second of two said materials, while the sputtered matter ejected from said sputter zone of the second of two said materials is deposited upon the surface of deposition zone of the first of two said materials. In this embodiment, the positions of each sputter zone and deposition zone of each said material are fixed relative to the chamber, said materials are moving synchronously in mutually opposite parallel directions, and the distance between the engineered surfaces of said materials is about or exceeds 5 cm (FIG. 4).

When the trans-zone sputtering is applied for engineering of the surfaces of two identical but separate materials simultaneously, said identical materials may be selected from the group of plastics, or from the group of metals.

When the trans-zone sputtering is applied for engineering of the surfaces of two different materials simultaneously, one of said different materials may be selected from the group of plastics, the second of said different materials selected from but not limited to the group of metals.

In another embodiment of the present invention, both said materials are polymer-based materials; one of said materials may be selected from, but not limited to, the group of organic or fluorine-organic polymers, and the second of said materials may be selected from, but not limited to, the group of silicon-organic polymers.

Also according to the present invention, both said materials may be selected from the group of metals.

If metal or metals are subjected to surface engineering by the trans-zone sputtering technique, a special precaution must be undertaken to prevent the high-voltage breakdown between the magnetron cathode and engineered material. The simplest solution is surface insulation of the magnetron cathode with a dielectric, such as an attached thin plate or a deposited dielectric layer while using the RF voltage mode. However, other solutions based on properly designed electrical power supply circuits are also possible.

In an important complimentary embodiment of the present invention, an active gas containing doping elements, including but not limited to carbon, silicon, oxygen, nitrogen, boron and/or one or combination of metallic elements, is supplied into the vacuum chamber during the sputtering/deposition process, preferably directly to the space in proximity of the deposition zone.

Continuous trans-zone sputtering provides greater than 90% utilization rate along the entire length of the tape except its beginning portion and end portion. In the case of very wide tapes, such as 10 to 20-ft wide tapes, a partial loss of sputtered material would occur mostly along the edges in the area with a width of about or less than the distance between the sputter zone and the deposition zone, and it would typically be about or below 1% of the total.

In fact, sputtering would not result with the actual loss of the material because it provides the necessary cleaning in situ (in chamber) prior to deposition. Thus, instead of the usually required special cleaning operation which requires additional operational time and labor, the invented method provides self-cleaning.

Furthermore, because no special target is needed for trans-zone sputtering, the target replacement which usually consumes essential operational time and labor, is completely excluded.

The trans-zone sputtering is a magnetron technology which is completely free from use of an expensive consumable target.

There is no need for water cooling of the magnetron assembly. As a result, the entire magnetron assembly may be located inside the chamber, and it does not experience the force of atmospheric pressure. This brings further advantages: the cathode assembly is thinner, the magnetic design is optimized, and the effectiveness of sputtering, sputtering/power density ratio and energy use all improve. It also reduces the magnetron weight, thus simplifying its installation in the chamber and allowing its movable design.

An additional advantage is an exceptional uniformity of both sputtering and deposition processes and smoothness of the resulted surfaces due to the high speed movement of the consuming and “growing” surfaces relative to the cathode assembly.

Where it is applicable, especially in the precise surface engineering and super-thin film deposition technologies, the Trans-Zone Sputtering is characterized with exceptionally high productivity; it does not require the expensive consumable targets, and in some instances it avoids the necessity of water cooling of the magnetron cathode assembly; it simplifies the maintenance of equipment, reduces labor requirements and virtually avoids emission.

The invented technology possesses certain innate physical and technical limitations, in particular the limits of achievable thickness of deposited materials due to high power density dissipating in material undergoing surface engineering by sputtering.

The mean depth of the temperature front penetration into the irradiated target is

h=˜{square root[3k(T),t]}cm,

where t is the time of irradiation, seconds; k(T), cm(sup2)/sec is temperature conductivity of irradiated material; k(T)=k/c, where K is its thermal conductivity, and c is the volume heat capacity.

If there is no effective heat sink from the back side of the irradiated material provided, and h>>D, where D is the thickness of the irradiated material, the temperature distribution across the thickness of the irradiated material is rather uniform. If h˜D, the surface temperature is about ˜1.65 of the average temperature across the thickness of the irradiated material. If h<<D, the elaborated energy heats mostly the surface layer ˜L.

The preferable embodiment of the present invention would satisfy the condition h>>D, while the surface temperature in such a condition only slightly exceeds the average temperature, should not be greater than the maximum temperature T* technically feasible for the target material, taking into account its intrinsic physical properties and the entire assembly requirements.

In such a condition the average target temperature is

T≦[(Nt)/(Dc)],

where N is the irradiation power density. In this formula t=d/V, where d is the required thickness of the deposited layer, V—is the deposition rate, e.g.

T˜{[(dN/V)/(Dc)]+T,room>]}

while it is required that T≦T*. Thus, the maximum achievable thickness of deposited layers in the trans-zone sputtering process may be evaluated as:

d≦[T*Dc(v/N)]

Indeed, the surface temperature would be greater but not exceeding ˜1.1 T e.g., the surface temperature may reach but will not exceed about 110% of the average temperature. On the other hand, actual average temperature increase will be a little lower of the above estimate due to a “cooling” effect via irradiation, e.g. transition from solid into non-condensed state of the sputtered flux and ejection energetic sputtered particles out from the irradiated surface, as well back scattering of still slightly energetic argon ions. These mutually compensated effects are of the same order of magnitude and may be neglected in this evaluation.

The inversed value of V/N, e.g. ratio between deposition rate and power density, may be also found in reference publications for different materials. The reference data may be used for an approximate evaluation, while the exact value depends on the specific design of magnetron assembly and should be defined experimentally.

As an example, consider Teflon characterized with the following properties: density ˜2.24 g/cm³, heat capacity c−1 J/g K, and thermal conductivity 2.3-2.5 W/mK in the technically important temperature range of 300 to 600 K. The sputtering rate of Teflon via irradiation by the argon ions with energy ˜1000 eV based on our experience is about or exceeds 6.0 {(nanometer/second)/([W/cm(sup2)]} at ˜300K and strongly increases with the target temperature. The maximum technically feasible temperature for Teflon T*=600 K, and hence the maximum achievable thickness of deposited Teflon films in the trans-zone sputtering process may be evaluated as

(d,nanometers)<(0.4D,micrometers),

while it is assumed that h(t)>>D. Hence, for 100-micrometer thick Teflon tape the maximum achievable thickness of deposited Teflon films in the trans-zone sputtering process is about 40 nm.

At the power density of 10 W/cm(sup2), RF the deposition time of 40-nm thick film would be 0.67 sec, and the mean depth of the temperature front penetration into the irradiated Teflon target would be h(t)=˜0,14 cm, e.g. the condition h(t)>>D is actually satisfied.

Similar although slightly different (small deviations) evaluations of the maximum achievable thickness are justified for other high-temperature plastics, such as polyimides, aromatic polyamides, polyoxybenzoates, silicon-organic polymers, and fluoro-polymers.

Typically, most polymers possess innate nanopores causing the eventual penetration of chemical agents through polymeric films, walls of the vessels, etc. It is understood from a general knowledge and from the practices of the prior art, that vapor deposition, especially from a relatively high energy flux generated by sputtering, produces a more uniform, dense and pore free layer. In many cases, such as chemically ultra-resistant materials as Teflon, a deposition of a dense surface layer of the same material would be especially desirable. The Trans-Zone Sputtering technique would be most effective for such applications.

In the case of metals, the condition h(t)>>D is almost always satisfied due to their high thermal conductivity, but the power consumption during the sputtering is one order, or even two orders of magnitude higher, and the maximum achievable thickness is correspondingly lower:

Aluminum characterized with heat capacity 25.1 J/Mol K=0.93 J/g K, density 2.7 g/cm(sup3), thermal conductivity 218 W/m K, sputtering rate/power density ratio in the above defined conditions ˜0,7{(nanometer/second)/([W/cm(sup2)]} at 300K. Hence, for 100-micrometer thick aluminum tape the maximum achievable thickness of deposited films in the trans-zone sputtering process is about 5 nm.

This thin surface layer will effectively improve surface of many materials.

Besides a higher density and uniformity, the Trans-Zone Sputtering would also cure the shallow surface mechanical defects and will close the grain boundaries commonly causing the crack nucleation, as well as corrosion in metals. In high-melting materials, like many transition metals and ceramics, the nanostructured or even amorphous surface layer would be formed as the result of the surface engineering by Trans-Zone Sputtering technique.

Similar evaluations of the maximum achievable thickness of deposited films in the trans-zone sputtering process for some other metals are:
Copper: 10 nm;
Iron, Nickel, Cobalt: 4 nm;
Silver: 20 nm.

NOTE: all the above estimates of the maximum achievable thickness of deposited films in the trans-zone sputtering process are based on a regular magnetron design without special optimization available based on thin water-free assembly located inside of vacuum chamber. This additional optimization would increase V/N ratio between deposition rate and power density, and thus increase achievable film thickness.

The invention is illustrated further by the following examples.

### EXAMPLE 1

In the below example a 200-micrometer thick Teflon tape underwent surface engineering with the purpose to close superficial nano-pores in the typical diameter range of 1 nm to 4 nm. The engineering was conducted using a rectangular magnetron; the width of the sputter zone is 8″, and the sputtered and deposited layers are 10-nm thick. The power density is 10 W/cm (sup2), RF.

The distance between the tape and magnetron cathode is 2 mm.

Note: this 2-mm gap is designated for decreasing the heat exchange between the tape and magnetron cathode; the exact width of the gap is not critical, and even occasional touching between tape and cathode will not result in damage.

The deposition time of 10 nm thick film is 0.5 second, the tape speed is 24 m/min. The step-wise procedure is as follows:
1. Two tapes are installed in the chamber in accordance with FIG. 4.
2. The chamber closed.
3. The mechanical pumping line open.
4. Pressure in chamber reached 0.1 Pa.
5. Turbomolecular pump switched on.
6. Pressure in chamber reached 10(sup −4) Pa.
7. Argon supply open as pre-determined
8. The drive mechanisms are switched on for both tapes simultaneously.
9. The tapes' speed of 24 m/min achieved.
10. The high voltage applied on magnetrons 2 and bias electrode 4
11. (note: power supply switched on automatically when the constant tape speed achieved).
12. When both tapes have run their entire length, except the end parts, the source rolls 5 and electrodes 4 switched off, the rolls 5 and 11 are stopped, and the power supply automatically and instantly switched off.
13. The vacuum system cooled off.
14. The air pressure in chamber equalized with outside atmospheric pressure.
15. The chamber opened.
16. The tapes are cut between electrodes 4 and rolls 11.
17. The rolls 11 with treated tapes are removed from chamber.

Observations: the tapes are hot (˜100 degree C.).

### EXAMPLE 2

The copper tapes and polyimide tape are installed in geometry shown on FIG. 4, similarly to the Example 1. The magnetron cathode in the copper branch of the unit is coated with 3 micrometer thick insulating diamond-like coating. The distance between the copper tape and the cathode surface, as well as between polyimide tape and respective cathode surface is 2 mm. The tapes' speed is 8 m/min, sputtering and deposition time for any specific area on the tapes is 1.5 seconds.

Final thickness of the copper layer upon polyimide is 8 nm. The copper layer is deposited instantly after cleaning of the polyimide substrate by ion sputtering and possesses high adhesion to polyimide and uniformity. Typically in the case of fast moving tape, the variation in uniformity will be less than 0.1% within 1 inch. Uniformity of composition and thickness is much better than plus/minus 1% within 1 m of length.

With foil, 20-40 microns, and you have a couple of centimeters it's about 10-50 m long), but in industry 1 m diameter and 40 microns thick, the average length will be 1.5 m; it may be used as the ground layer for copper plating.

Final thickness of polyimide layer upon copper tape is 32 nm. Polyimide layer provides anti-corrosion protection for the coated cooper surface.

1.5 m×(0.5 m/40 microns)=1.5 m×(500000 microns/40 microns)=18750 m=18.75 km.

It is therefore apparent that the invention accomplishes its intended objectives. While embodiments of the invention have been described in detail, that is done for the purpose of illustration, not limitation.

1. Method for surface engineering of materials using ion sputtering and vacuum deposition, comprising:
sputtering material from a first location, or sputtering zone, on a surface of a substrate, and
depositing said sputtered material at a second location, or deposition zone, on a surface of a substrate,
said substrate comprises said sputtering zone and said deposition zone, the method is named trans-zone sputtering.

2. Method of surface engineering with ion sputtering and vacuum deposition technique according to claim 1, wherein said sputtering and said deposition realized at different locations, or zones, of the surface of the same moving substrate.

3. Method of surface engineering by trans-zone sputtering according to claim 2, wherein said sputter zone and said deposition zone located on the surface of the same moving substrate, the sputtered matter ejected from said sputter zone, deposited upon the surface of said deposition zone, both zones are moving synchronously relatively to the surface of said substrate.

4. Method of surface engineering by trans-zone sputtering according to claim 1, wherein said engineering realized upon the surfaces of two separated substrates synchronously, each of said separated substrates comprises said sputter zone and said deposition zone, the sputtered matter ejected from said sputter zone of the first of two said substrates deposited upon the surface of the deposition zone of the second of two said substrates, the sputtered matter ejected from said sputter zone of the second of two said substrates deposited upon the surface of deposition zone of the first of two said substrates, both sputter zone and deposition zone of each said substrate fixed relatively to the ground, two said substrates are moving in parallel way in opposite directions (counter flow).

5. Method for surface engineering according to claim 3, wherein the positions of said sputter zone and said deposition zone fixed relatively to the ground, said substrate comprising said sputter zone and said deposition zone is moving relatively to the ground, said moving substrate is preferably possesses but not limited with shape of a tape.

6. Method for surface engineering according to claim 3, wherein said substrate comprising said sputter zone and said deposition zone fixed relatively to the ground, said sputter zone and said deposition zone are continuously moving relatively to the ground.

7. Method for surface engineering according to claim 1, wherein said sputtering realized with DC or RF planar magnetron.

8. Method for surface engineering by trans-zone sputtering according to claim 2, especially surface engineering of dielectric materials, wherein a negative potential applied to the bias electrode located from the back side of deposition zone, said negative potential applied continuously or by pre-defined timing regime during the deposition, including but not limiting the pulse regime, wherein the pulse period time does not exceed the mean deposition time of five mono-layers.

9. Method for surface engineering according to claim 5, wherein said substrate comprising said sputter zone and said deposition zone is the tape moving relatively to the ground, the length of tape is at least ten times greater than the combined length of the said sputter zone length and said deposition zone length, said moving tape in said sputter zone being in mechanical contact with magnetron cathode or on the distance not exceeding 5 mm.

10. Method for surface engineering according to claim 5, wherein said continuously moving tape bended by driving mechanism on 180 degree between said sputter section and deposition section, said sputter section is moving in the opposite parallel direction to said deposition section, the distance between the surfaces of said sections is about or exceeds 5 cm, said surface engineering conducted upon one side of said material.

11. Method for surface engineering according to claim 5, wherein said surface engineering conducted from both sides of said material in one continuous process, said continuously moving tape passes consecutively the first pair of sputter section and deposition section wherein the first surface of said moving tape engineered, and the second pair of sputter section and deposition section wherein the second surface of said moving tape engineered, the orientation of said tape in inversed on 180 degree with driving mechanism between said first pair of sputter section and deposition section and the second pair of sputter section and deposition section.

12. Method for surface engineering according to claim 5, wherein said continuously moving tape bended between said source section and said substrate section by driving mechanism on the angle at least 90 degree but no greater than 160 degree, an additional flux of ions, atoms and/or low-molecular radicals directed to said substrate section of said moving tape from additional source, such as second magnetron, or plasmatron, or evaporating source, or ion gun.

13. Method of surface engineering by trans-zone sputtering according to claim 4, wherein said engineering realized upon the surfaces of two separated substrates synchronously, said separated substrates consist of different materials, each of said separated materials possess said sputter zone and said deposition zone, the sputtered matter ejected from said sputter zone of the first of two said materials deposited upon the surface of deposition zone of the second of two said materials, the sputtered matter ejected from said sputter zone of the second of two said materials deposited upon the surface of deposition zone of the first of two said materials, the positions of each sputter zone and deposition zone of each said material fixed relatively to the ground, said materials are moving synchronously in mutually opposite parallel directions.

14. Method of surface engineering by trans-zone sputtering according to claim 4, wherein said engineering realized upon the surfaces of two identical separated substrates synchronously, each of said identical separated substrates possess said sputter zone and said deposition zone, the sputtered matter ejected from said sputter zone of each said material deposited upon the surface of deposition zone of the other said material said identical materials selected from but not limited with group of plastics or group of metals.

15. Method of surface engineering by trans-zone sputtering according to claim 13, wherein, one of said different materials selected from but not limited with group of plastics, the second of said different materials selected from but not limited with group of metals.

16. Method of surface engineering by trans-zone sputtering according to claim 13, wherein both said materials are polymer-based materials, one of said materials selected from but not limited with the group of organic or fluorine-organic polymers, the second of said materials is selected from the group of silicon-organic polymers.

17. Method of surface engineering by trans-zone sputtering according to claim 13, wherein both said materials selected from group of metals.

18. Method for surface engineering according to claim 1, wherein an active gas containing doping elements, including but not limited carbon, silicon, oxygen, nitrogen, boron and/or one or combination of metallic elements, supplied into the vacuum chamber, preferably directly to the space in proximity of the deposition zone.
